(19) United States
(12) Patent Application Publication
(10) Pub. No.: US 2013/0235549 A1
(43) Pub. Date: Sep. 12, 2013

(54) FIXING MECHANISM AND ELECTRONIC DEVICE USING THE SAME

(71) Applicant: XIAO-HUI ZHOU, Shenzhen City (CN)

(72) Inventor: XIAO-HUI ZHOU, Shenzhen City (CN)

(73) Assignees: HON HAI PRECISION INDUSTRY CO., LTD., Tu-Cheng (TW); HONG FU JIN PRECISION INDUSTRY (Shenzhen) CO., LTD., Shenzhen City (CN)

(21) Appl. No.: 13/600,335

(22) Filed: Aug. 31, 2012

(30) Foreign Application Priority Data
Mar. 7, 2012 (CN) 201210057644.5

(51) Int. Cl. H05K 7/14

(52) U.S. Cl. 361/810

(57) ABSTRACT

An electronic device comprises a housing, an electronic component fixed to the housing, and a fixing mechanism. The electronic component defines first and second latching notches. The fixing mechanism comprises a first latching component, a second latching component opposite to the first latching component, a first positioning post, and a second positioning post opposite to the first positioning post. The first and second latching components are capable of hooking over opposite ends of the electronic component, and fixing the electronic component to the housing in a first direction. The first and second positioning posts are capable of latching to the first and second latching notches, for fixing the electronic component to the housing in a second direction perpendicular to the first direction.

### BACKGROUND

1. Technical Field

The present disclosure relates to electronic devices; and particularly, to an electronic device having a fixing mechanism.

2. Description of Related Art

Electronic devices, such as disc players and notebook computers, include a housing and at least one electronic component, for example, a heat sink plate used for dissipating the heat produced by the electronic device. The heat sink plate is typically assembled and fixed to the housing by mean of screws. However, auxiliary tools are required for disassembly and assembly of the heat sink plate, thereby causing inconvenience and constraints on operation.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an electronic device with a fixing mechanism.

FIG. 2 is a partially disassembled view of the electronic device of FIG. 1.

FIG. 3 is a partially assembled view of the electronic device of FIG. 2.

### DETAILED DESCRIPTION

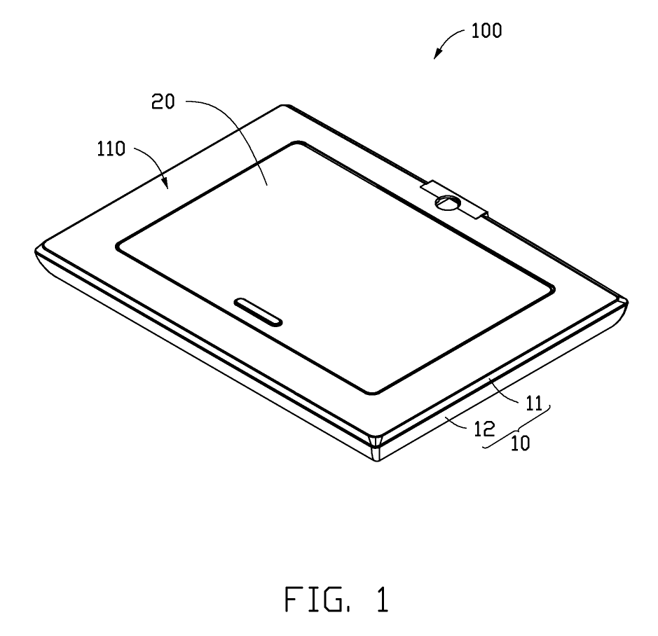

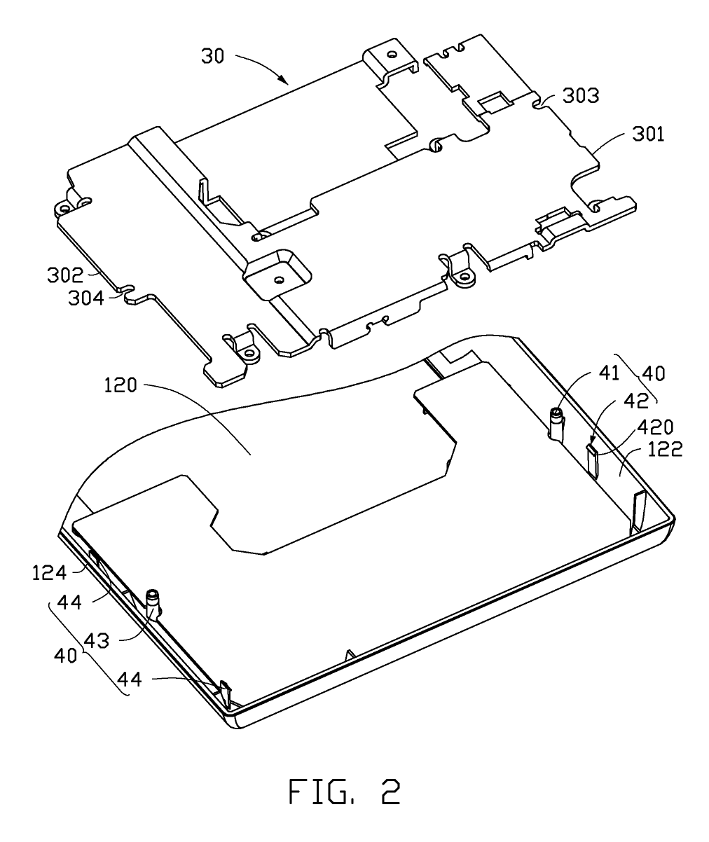

FIGS. 1 and 2 illustrate an embodiment of an electronic device 100. The electronic device 100 includes a housing 10, a cover 20, an electronic component 30 received in the housing 10, and a fixing mechanism 40. The cover 20 is rotatably coupled to the housing 10 and is capable of being opened and closed relative to the housing 10. The electronic device 100 may be a notebook computer, a disc player, or other electronic device. In the embodiment, the electronic device 100 is a disc player.

The housing 10 is substantially rectangular, and includes a top case 11 having a top plate 110, and a bottom case 12. The top case 11 cooperates with the bottom case 12 to define a receiving space (not labeled) for receiving the electronic component 30, the fixing mechanism 40 and other electronic components 50, for example, a circuit board. The bottom case 12 includes a bottom plate 120 opposite to the top plate 110, a first sidewall 122 and a second sidewall 124 extending from opposite rims of the bottom plate 120.

The electronic component 30 is substantially rectangular, and is mounted on the bottom plate 120. In the embodiment, the electronic component 30 is a heat sink component for dissipating the heat produced by the electronic device 100. The electronic component 30 includes a first rim 301 corresponding to the first sidewall 122, and a second rim 302 opposite to the first rim 301. The first rim 301 is recessed to define a semi-circular first latching notch 303. The second rim 302 is recessed to define a semi-circular second latching notch 304. In other embodiments, the shape of the first and second latching notches 303, 304 may be elliptical or some other shape.

The fixing mechanism 40 is used for fixing the electronic component 30 to the bottom plate 120. The fixing mechanism 40 is positioned on the bottom case 12, and includes a first positioning post 41, a first latching component 42, a second positioning post 43, and two spaced second latching components 44.

The first and second positioning posts 41, 43 perpendicularly protrude from the bottom plate 120 and are opposite to each other. The first positioning post 41 is arranged adjacent to the first sidewall 122. The second positioning post 43 is arranged adjacent to the second sidewall 124. The shape of the first and second positioning posts 41, 43 is substantially cylindrical, for engaging with the first and second latching notches 303, 304.

The first latching component 42 and the two second latching components 44 perpendicularly protrude from the bottom plate 120. The first latching component 42 is arranged adjacent to the first sidewall 122 and is spaced from the first positioning post 41. The two second latching components 44 are opposite to the first latching component 42 and are arranged adjacent to the second sidewall 124. The second positioning post 43 is sandwiched between the two second latching components 44 and is spaced from each second latching component, for engaging with the second latching notch 304. In the embodiment, the first and second latching components 42, 44 are hooks which have the same configuration. The first latching component 42 is made of elastic material, and maintains a predetermined gap from the first sidewall 122, for allowing the first latching component 42 to deform toward the first sidewall 122. The two second latching components 44 are made of rigid material, for resisting the electronic component 30. In other embodiment, the two second latching components 44 can be made of other materials.

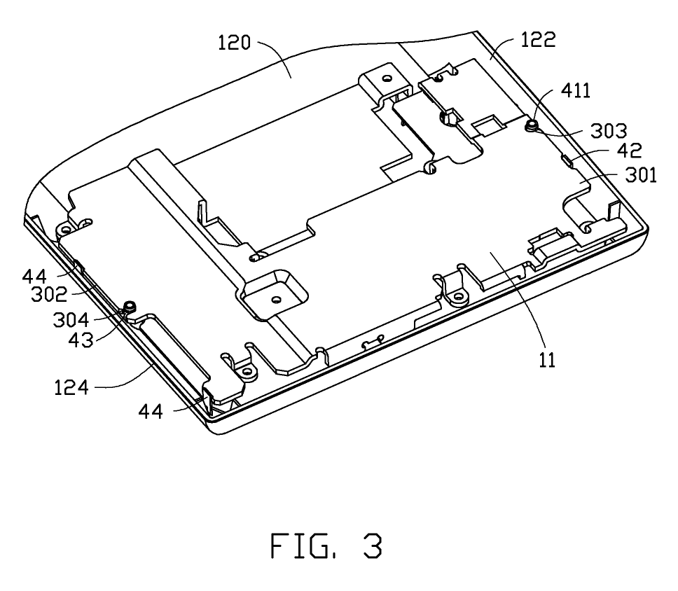

Referring to FIG. 3, to secure the electronic component 30 to the bottom plate 120, firstly, the second positioning post 43 is received in the second latching notch 304, the two second latching components 44 hook over opposite ends of the second rim 302. Secondly, the electronic component 30 is pressed down to deform the first latching component 42, such that the first positioning post 41 is received in the latching notch 303 and the first latching component 42 hooks over the first rim 301. As a result, the electronic component 30 is secured to the bottom plate 120.

After assembly, opposite ends of the electronic component 30 are limited by the first and second positioning posts 41 and 42, thus the electronic component 30 is prevented from moving in a first direction parallel to the bottom plate 120. The first and second latching components 42 and 43 hook over and grip opposite ends of the electronic component 30, thus, the electronic component 30 is prevented from moving in a second direction perpendicular to the bottom plate 120.

In disassembly, the first latching component 42 is elastically deformed and disengages from the electronic component 30, and the first rim 301 is raised relative to the bottom plate 120, for allowing the electronic component 30 to disengage from the first positioning post 41. Then the second rim 302 is pulled away relative to the bottom plate 120, and disengages from the second positioning post 43 and the two second latching components 44, thus, the electronic component 30 can be disassembled from the bottom plate 120 without the use of a tool.

The fixing mechanism 40 is capable of fixing the electronic component 30 to the bottom case 12, and is capable of allowing assembly and disassembly of the electronic component 30 to/from the bottom case 12 without any tool, such that the assembly and disassembly process can be quickly and conveniently implemented. The position and the number of the first and second positioning posts 41,43, and the first and second latching components 42, 44 can be changed according to need, and the number and the position of the fixing mechanism 40 may also be changed according to need.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
a housing;
an electronic component fixed to the housing and defining first and second latching notches; and
a fixing mechanism positioned on the housing for securing the electronic component to the housing, the fixing mechanism comprising:
a first latching component protruding from the housing;
a second latching component protruding from the housing and opposite to the first latching component;
a first positioning post protruding from the housing; and
a second positioning post protruding from the housing and opposite to the first positioning post;
wherein the first and second latching components are capable of hooking over opposite ends of the electronic component for preventing the electronic component from disengaging from the housing in a first direction; the first and second positioning posts are capable of being latched to the corresponding first and second latching notches, for prevent the electronic component from disengaging from the housing in a second direction perpendicular to the first direction.

2. The electronic device as claimed in claim 1, wherein the housing comprises a bottom plate, a first sidewall and a second sidewall opposite to the first sidewall; the first direction is perpendicular to the bottom plate, and the second direction is parallel to the bottom plate.

3. The electronic device as claimed in claim 2, wherein the first and second positioning posts protrude from the bottom plate; the first positioning post is adjacent to the first sidewall and is spaced from the first latching component; the second positioning post is adjacent to the second sidewall and is spaced from the second latching component.

4. The electronic device as claimed in claim 2, wherein the first and second latching components protrude from the bottom plate; the first latching component is adjacent to the first sidewall, and the second latching component is adjacent to the second sidewall.

5. The electronic device as claimed in claim 1, wherein the first and second latching components are hooks.

6. The electronic device as claimed in claim 1, wherein the first latching component is made of elastic material.

7. The electronic device as claimed in claim 1, wherein the second latching component is made of rigid material.

8. The electronic device as claimed in claim 1, wherein the first and second positioning posts are cylindrical-shaped.

9. The electronic device as claimed in claim 1, wherein the shape of the first and second latching notches is semi-circular.

10. A fixing mechanism for securing an electronic component to a housing of an electronic device, the electronic component defining first and second latching notches, the fixing mechanism comprising:
a first latching component protruding from the housing;
a second latching component protruding from the housing and opposite to the first latching component;
a first positioning post protruding from the housing; and
a second positioning post protruding from the housing and opposite to the first positioning post;
wherein the first and second latching components are capable of hooking over opposite ends of the electronic component for preventing the electronic component from disengaging from the housing in a first direction; the first and second positioning posts are capable of being latched to the corresponding first and second latching notches, to prevent the electronic component from disengaging from the housing in a second direction perpendicular to the first direction.

11. The fixing mechanism as claimed in claim 10, wherein the housing comprises a bottom plate, a first sidewall and a second sidewall opposite to the first sidewall; the first direction is perpendicular to the bottom plate, and the second direction is parallel to the bottom plate.

12. The fixing mechanism as claimed in claim 11, wherein the first and second positioning posts protrude from the bottom plate; the first positioning post is adjacent to the first sidewall and is spaced from the first latching component; the second positioning post is adjacent to the second sidewall and is spaced from the second latching component.

13. The fixing mechanism as claimed in claim 11, wherein the first and second latching components protrude from the bottom plate; the first latching component is adjacent to the first sidewall, and the second latching component is adjacent to the second sidewall.

14. The fixing mechanism as claimed in claim 10, wherein the first and second latching components are hooks.

15. The fixing mechanism as claimed in claim 10, wherein the first latching component is made of elastic material.

16. The fixing mechanism as claimed in claim 10, wherein the second latching component is made of rigid material.

17. The fixing mechanism as claimed in claim 10, wherein the first and second positioning posts are cylindrical-shaped.

18. The fixing mechanism as claimed in claim 10, wherein the shape of the first and second latching notches is semi-circular.
